(19) United States
(12) Patent Application Publication
(10) Pub. No.: US 2026/0144000 A1
(43) Pub. Date: May 21, 2026

(54) SUPPORT APPARATUS

(71) Applicant: GUDENG PRECISION INDUSTRIAL CO., LTD., New Taipei City (TW)

(72) Inventors: MING-CHIEN CHIU, New Taipei City (TW); CHIA-HO CHUANG, New Taipei City (TW); CHENG-WU CHUNG, New Taipei City (TW); JING-JIE SOU, New Taipei City (TW); YU-HSIEN LEE, New Taipei City (TW); TZU-HSIANG WEI, New Taipei City (TW)

(73) Assignee: GUDENG PRECISION INDUSTRIAL CO., LTD., New Taipei City (TW)

(21) Appl. No.: 19/389,073

(22) Filed: Nov. 14, 2025

Related U.S. Application Data
(60) Provisional application No. 63/720,780, filed on Nov. 15, 2024.
(60) Provisional application No. 63/722,082, filed on Nov. 19, 2024.

(51) Int. Cl. H01L 21/673; H01L 21/687

(52) U.S. Cl. CPC H10P 72/1921; H10P 72/7624

(57) ABSTRACT

A support apparatus is configured to be disposed in a semiconductor container. The support apparatus includes a body and a bearing surface. The bearing surface is located on an upper surface of the body. The bearing surface includes a first inclined surface gradually protruding obliquely from the bearing surface toward an opening of the semiconductor container, and a second inclined surface gradually protruding obliquely toward an inner rear wall of the semiconductor container. The bearing surface is configured to bear a contact surface of a semiconductor substrate. The contact surface makes surface contact along the first inclined surface and along the second inclined surface that are different inclined surfaces. The support apparatus can effectively reduce deformation during support and contamination caused during frictional contact.

This non-provisional application claims priority under 35 U.S.C. § 119(e) on U.S. provisional Ser. No. 63/722,082 filed on Nov. 19, 2024 and U.S. provisional Ser. No. 63/720,780 filed on Nov. 15, 2024, the entire contents of which are hereby incorporated by reference.

### BACKGROUND OF THE INVENTION

### 1. Field of the Invention

The present disclosure relates to an assembly of a semiconductor container, and in particular, to a support apparatus that can be assembled in the semiconductor container and carries a semiconductor substrate.

### 2. Description of the Related Art

During production and transportation of a semiconductor, a semiconductor container is usually used to store and place a semiconductor substrate such as a wafer, a photomask, a PCB, or a glass substrate. With development of semiconductor processing, requirements on production efficiency, a yield rate, and costs are increasingly high. How to improve the structure of the semiconductor container, improve operational efficiency, and/or reduce vibration of the semiconductor substrate during transportation, to improve the yield rate of processing and reduce overall cost, has become an increasingly important topic.

A known semiconductor container usually includes a container body, a door, and a support member. The container body has space that can accommodate a semiconductor substrate. The door is disposed at an outward opening of the space of the container body, and can cover the opening in an openable manner, to close the space accommodating the semiconductor substrate. The support member is disposed inside the space of the container body, and configured to support the semiconductor substrate.

### BRIEF SUMMARY OF THE INVENTION

However, when a semiconductor substrate accommodated by a semiconductor container has a large size, is thin, or has low rigidity, the semiconductor substrate easily slides relative to support members on two sides, and frictional particles and even collisions may occur.

Referring to FIG. 1, through research, it has been discovered that one of the reasons causing the foregoing phenomenon is that a semiconductor substrate P slightly deforms due to gravity. As a result, warping occurs at a position in contact with a support rib R of a support member, a contact area with the support rib R is reduced, and only a line contact relationship is formed with the support rib R. In addition, even though an intermediate lifting member M is added to space of a container body, an effect of improving the phenomenon is limited.

Using a substrate with a length being 60 cm, a width being 60 cm, a thickness being 1 mm, and a density being 2.38 g/cm³ as an example, the weight of the substrate is approximately 856.8 g. After the substrate is mounted into a semiconductor container including support ribs R on two sides and an intermediate lifting member M, a warping dimension of the substrate on two sides relative to the support ribs R can reach approximately 0.05 mm. For a substrate whose thickness is reduced to 0.5 mm but other conditions are the same, a warping dimension of the substrate on two sides relative to the support ribs R can further reach approximately 0.07 mm.

In view of defects of the foregoing known technologies, the inventor feels that the prior art was inadequate, and therefore performs researching for overcoming. A support apparatus has been developed successfully, so that a phenomenon of back and forth sliding of the semiconductor substrate can be reduced, and/or a contact area with the semiconductor substrate can be increased.

In addition, the support apparatus of the present disclosure can further reduce particles caused by friction, or reduce particles falling onto the semiconductor substrate below.

For directional terms or similar terms thereof in the present disclosure, for example, “front”, “rear”, “left”, “right”, “upper (top)”, “lower (bottom)”, “inner”, “outer”, and “side”, mainly refer to directions in the accompanying drawings. The directional terms or similar terms thereof are only used to help describe and understand embodiments of the present disclosure, and are not intended to limit the present disclosure.

The terms “one” or “a” as used herein for elements and components described in the present disclosure are only for convenient use and provides a common definition of the scope of the present disclosure, and should be interpreted as including one or at least one in the present disclosure. In addition, unless clearly indicating another meaning, a concept of being single also includes a condition of being plural.

Similar terms such as “bind”, “combine”, or “assemble” in the present disclosure mainly include forms such as being capable of being separated without breaking components after connection, enabling components to be incapable of being separated after connection, or the like, and can be selected by a person of ordinary skill in the art based on material or assembly requirements of the to-be-connected components.

To achieve the foregoing objective and other objectives, the present disclosure provides a support apparatus, configured in a semiconductor container. The support apparatus includes a body; and a bearing surface located on an upper surface of the body. The bearing surface includes a first inclined surface, gradually protruding obliquely from the bearing surface toward an opening of the semiconductor container; and a second inclined surface, where the second inclined surface gradually protrudes obliquely toward an inner rear wall of the semiconductor container. The bearing surface is configured to bear a contact surface of a semiconductor substrate, and the contact surface makes surface contact along the first inclined surface and along the second inclined surface that are different inclined surfaces.

In the foregoing support apparatus, the first inclined surface and the second inclined surface each may form an included angle less than 7 degrees with a horizontal surface.

The present disclosure further provides a support apparatus, configured in a semiconductor container. The support apparatus includes a body; and a bearing surface, including at least one fault portion, and located on an upper surface of the body. The bearing surface includes a first inclined surface, gradually protruding obliquely from the bearing surface toward an opening of the semiconductor container; and a second inclined surface, where the second inclined surface gradually protrudes obliquely toward an inner rear wall of the semiconductor container. The bearing surface is configured to bear a contact surface of a semiconductor substrate, and the contact surface makes surface contact along the first inclined surface and along the second inclined surface that are different inclined surfaces.

In the foregoing support apparatus, when there may be a plurality of fault portions, the bearing surface may be presented as step-shaped fault portions with different heights and different areas. The step-shaped fault portions are configured to bear the contact surface of the semiconductor substrate.

In the foregoing support apparatus, the body includes a lower surface opposite to the bearing surface. The lower surface and the bearing surface have a thickness. The plurality of fault portions are based on the lower surface. The plurality of fault portions and the lower surface may be gradually thinned, to present the step-shaped fault portions with the different heights and the different areas.

In the foregoing support apparatus, a height between adjacent fault portions may be less than 1 mm, and a width therebetween may be less than 2 mm.

In the foregoing support apparatus, the first inclined surface and the second inclined surface each may form an included angle less than 7 degrees with a horizontal surface.

The present disclosure further provides a support apparatus, configured in a semiconductor container. The support apparatus includes a body; and a bearing surface, including a plane and at least one extension portion extending upward from the plane. At least one particle collection slot is defined between the plane and the extension portion. The bearing surface is located on an upper surface of the body. The bearing surface includes a first inclined surface, gradually protruding obliquely from the bearing surface toward an opening of the semiconductor container; and a second inclined surface, where the second inclined surface gradually protrudes obliquely toward an inner rear wall of the semiconductor container. The bearing surface is configured to bear a contact surface of a semiconductor substrate, and the contact surface makes surface contact along the first inclined surface and along the second inclined surface that are different inclined surfaces.

In the foregoing support apparatus, when the support apparatus may be configured on a side wall inside the semiconductor container, the extension portion may extend upward from a middle and an outer side of the plane, to define at least two particle collection slots.

In the foregoing support apparatus, when the support apparatus may be configured at a middle position inside the semiconductor container, the extension portion may extend upward from a middle and two outer sides of the plane, to define at least two particle collection slots.

Based on this, the support apparatus of the present disclosure enables the semiconductor substrate to comply with guidance of the first inclined surface and the second inclined surface and be in a form in which there is slight sagging in the middle. Therefore, a sliding phenomenon does not easily occur, and particles caused by friction can be effectively reduced. In addition, a contact area with the semiconductor substrate can be increased by using the bearing surface of the support apparatus, to more stably support the semiconductor substrate, reduce a sliding risk of the semiconductor substrate when a support area is insufficient, and reduce the particles caused by friction. In addition, the support apparatus can further reduce, through disposition of the particle collection slot, particles falling onto the semiconductor substrate below, thereby improving a production yield rate.

### BRIEF DESCRIPTION OF THE DRAWINGS

FIG. 1 is a schematic diagram of a semiconductor substrate borne by a support apparatus in a known semiconductor container.

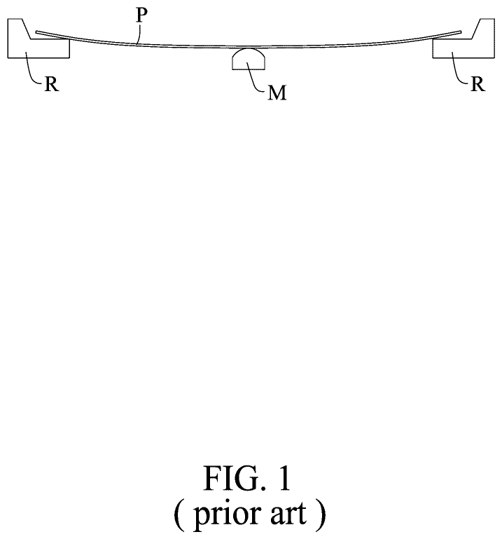

FIG. 2 is a diagram of a three-dimensional structure of a semiconductor container according to Embodiment 1 of the present disclosure.

FIG. 3 is a diagram of a cross-sectional view of a structure along a line A-A in FIG. 2.

FIG. 4 is a schematic diagram of back-and-forth oblique variation of a bearing surface of a support apparatus according to Embodiment 1 of the present disclosure.

FIG. 5 is a schematic diagram in which a bearing surface of a support apparatus is inclined downward according to Embodiment 1 of the present disclosure;

FIG. 6 is a schematic diagram of a semiconductor substrate borne by a support apparatus according to Embodiment 1 of the present disclosure.

FIG. 7 is a diagram of a partially enlarged view of a three-dimensional structure of a support apparatus according to Embodiment 1 of the present disclosure.

FIG. 8 is a diagram of a three-dimensional structure of a support apparatus according to Embodiment 2 of the present disclosure;

FIG. 9 is a diagram of a partial planar structure of a support apparatus according to Embodiment 2 of the present disclosure.

FIG. 10 is a schematic diagram of a cross-sectional view of a structure along a line B-B in FIG. 9, showing support of a semiconductor substrate.

FIG. 11 is a schematic diagram of a semiconductor substrate borne by a support apparatus according to Embodiment 3 of the present disclosure.

FIG. 12 is a schematic diagram of a semiconductor substrate borne by a support apparatus according to Embodiment 4 of the present disclosure.

### DETAILED DESCRIPTION OF THE INVENTION

To fully understand objectives, features, and effects of the present disclosure, the present disclosure is described in detail by using the following specific embodiments and with reference to the accompanying drawings. Descriptions are as follows.

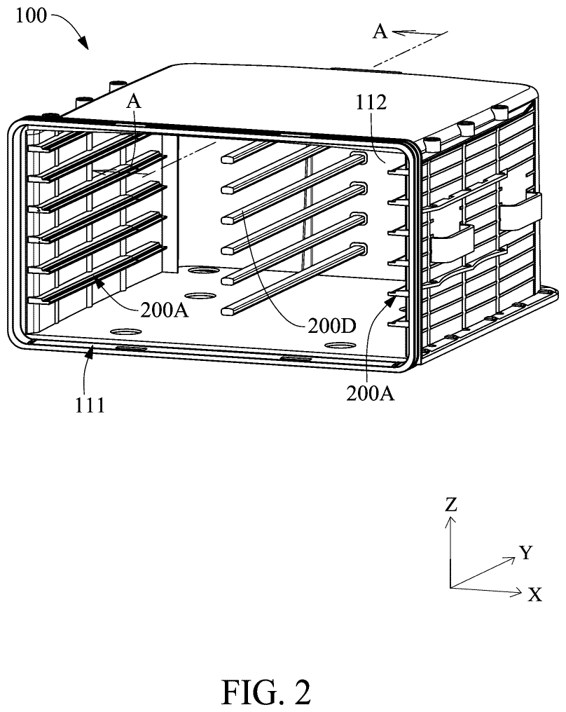

FIG. 2 shows a support apparatus 200A of Embodiment 1 of the present disclosure. The support apparatus 200A is configured in a semiconductor container 100, and is configured to support a semiconductor substrate. The semiconductor container 100 may be, for example, a loading device or a processing apparatus of a substrate carrier pod, a mask carrier pod, a carrier board carrier pod, or a carrier of another element during semiconductor processing. This is not limited in the present disclosure.

In an embodiment of the present disclosure, the support apparatus 200A may be used in a front opening semiconductor container, for example, a front opening unified pod (FOUP). The semiconductor container 100 has an opening 111, and an inner rear wall 112 opposite to the opening 111 is included inside the semiconductor container 100. In addition, it may be defined that the opening 111 is opposite to the inner rear wall 112 in a direction Y, which is a back-and-forth direction. A height direction of the semiconductor container 100 is a direction Z. A plurality of support apparatuses 200A of this embodiment may be configured on each of left and right sides that are opposite in a direction X inside the semiconductor container 100, and the plurality of support apparatuses 200A are spaced apart in a longitudinal direction.

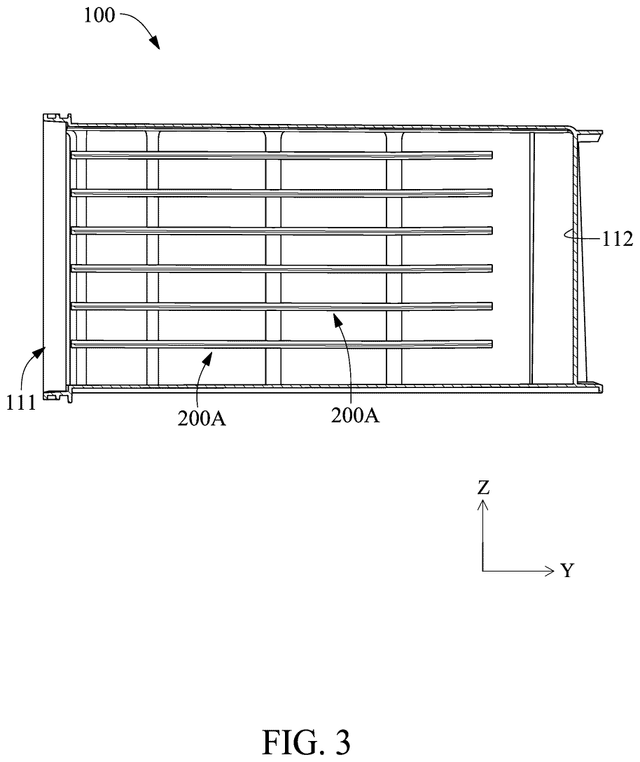

To be specific, referring to FIG. 2 and FIG. 3, the support apparatus 200A of this embodiment includes a body 1 and a bearing surface 2. The bearing surface 2 is located on an upper surface of the body 1, and the bearing surface 2 abuts against a contact surface of the semiconductor substrate. In some embodiments, the semiconductor container 100 may further include a plurality of support apparatuses 200D (intermediate lifting members) in another form. The plurality of support apparatuses 200D are arranged spaced apart in the longitudinal direction (for example, the direction Z) inside the semiconductor container 100, and one end of each of the support apparatuses 200D is connected to the inner rear wall 112 of the semiconductor container 100, so that the support apparatuses 200D and the support apparatuses 200A on the two sides support the semiconductor substrate together.

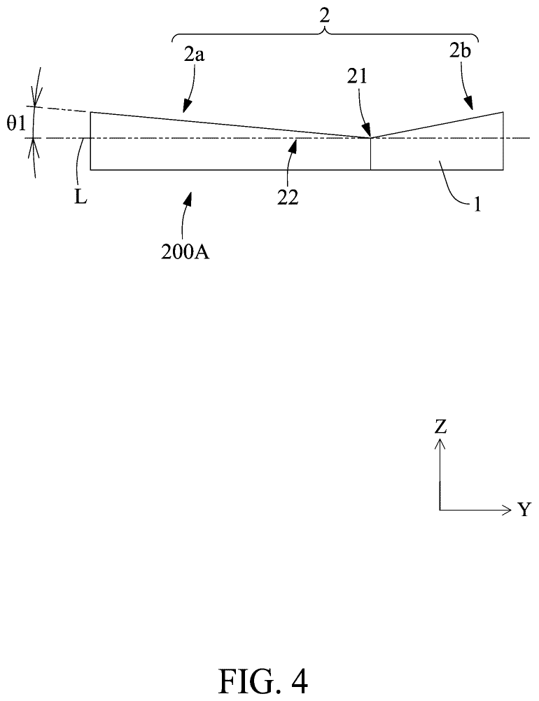

For ease of describing and displaying a part of detailed structural features of the support apparatus 200A, in the present disclosure, FIG. 4 is a schematic diagram of a condition in which the support apparatus 200A is presented in a front view in the direction X. FIG. 4 is merely an example, and a form of the support apparatus 200A in this embodiment is not limited by a ratio relationship between parts in FIG. 4.

Referring to FIG. 2, FIG. 3, and FIG. 4, in this embodiment, the bearing surface 2 of the support apparatus 200A may include a first inclined surface 2a and a second inclined surface 2b. The first inclined surface 2a is closer to the opening 111 of the semiconductor container 100 than the second inclined surface 2b. The first inclined surface 2a gradually protrudes obliquely from the bearing surface 2 toward the opening 111 of the semiconductor container 100. The second inclined surface 2b gradually protrudes obliquely toward the inner rear wall 112 of the semiconductor container 100.

In other words, the first inclined surface 2a is inclined downward from the front to the rear, the second inclined surface 2b is inclined upward from the front to the rear, and a lowest point 21 of the bearing surface 2 is located between the first inclined surface 2a and the second inclined surface 2b. FIG. 4 includes a horizontal surface L passing through the lowest point 21, and most of the first inclined surface 2a and most of the second inclined surface 2b are both above the horizontal surface L. The first inclined surface 2a and the second inclined surface 2b may be directly connected at the lowest point 21, or may be spaced apart by a short distance. This is not limited in the present disclosure.

Based on this, when the semiconductor substrate is placed in the semiconductor container 100 of this embodiment, even though the semiconductor substrate slightly deforms due to the gravity, the semiconductor substrate can comply with guidance of the first inclined surface 2a and the second inclined surface 2b, so that the contact surface of the semiconductor substrate makes surface contact along the first inclined surface 2a and along the second inclined surface 2b that are different inclined surfaces, and the semiconductor substrate is in a form in which there is slight sagging in the middle between a front end and a rear end. Therefore, potential energy and a contact area required for back and forth sliding of the semiconductor substrate can be improved, thereby improving stability. In addition, back and forth sliding of the semiconductor substrate can be effectively reduced, thereby effectively reducing particles caused by friction due to sliding of the semiconductor substrate.

In an embodiment of the present disclosure, the first inclined surface 2a and the second inclined surface 2 b of the bearing surface 2 each form an included angle θ1 less than 7 degrees with the horizontal surface L, and an inclined angle of the first inclined surface 2a and an inclined angle of the second inclined surface 2b may be the same or different. This is not limited in the present disclosure. In this way, a structural design of the bearing surface 2 of this embodiment can improve a defect in the prior art to an effect of reducing back and forth sliding of the semiconductor substrate, and excessive deformation of the semiconductor substrate is avoided.

In addition, in an embodiment of the present disclosure, in a range in which the bearing surface 2 is projected to the horizontal surface L along the direction Z, there is a center point 22 between the front end and the rear end. The lowest point 21 of the bearing surface 2 is preferably located between the rear end of the bearing surface 2 and the center point 22. In this way, even though the semiconductor substrate slides inside the semiconductor container 100, the semiconductor substrate tends to slide toward the inside of the semiconductor container 100, instead of sliding toward the opening of the semiconductor container 100.

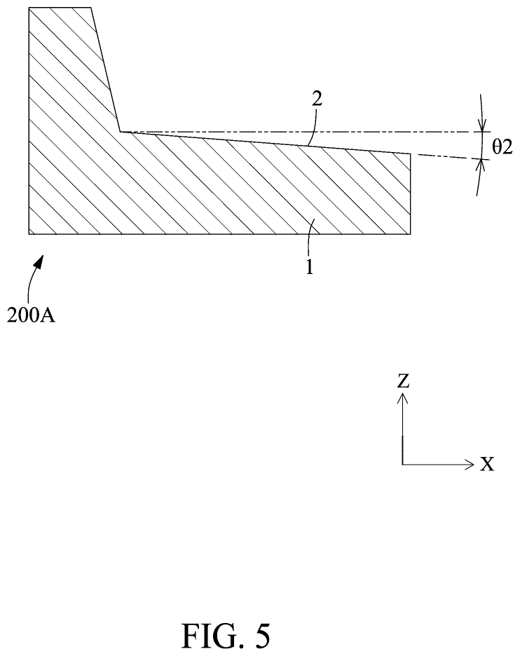

FIG. 5 is a schematic diagram of a cross section of the support apparatus 200A in the direction X and the direction Z. FIG. 5 is also a schematic diagram for ease of describing and displaying a part of detailed structural features of the support apparatus 200A, and is merely an example. The form of the support apparatus 200A in this embodiment is neither limited by a ratio relationship between parts in FIG. 5.

In an embodiment of the present disclosure, the bearing surface 2 of the support apparatus 200A may be a downward inclined surface inclined downward toward a free end. A downward inclined angle θ2 of the downward inclined surface may be set to below 3 degrees (including 3 degrees) and greater than 0 degree, such as 0.5 degrees. In this way, the bearing surface 2 of the support apparatus 200A of this embodiment can be easily produced and formed, and it is ensured that the contact surface of the semiconductor substrate placed in the semiconductor container 100 (shown in FIG. 2) can attach and contact to the corresponding bearing surface 2 to achieve surface contact, thereby increasing a contact area between the support apparatus 200A and the semiconductor substrate. Therefore, the semiconductor substrate is more stably supported, so that it is difficult for the semiconductor substrate to slide inside the semiconductor container 100.

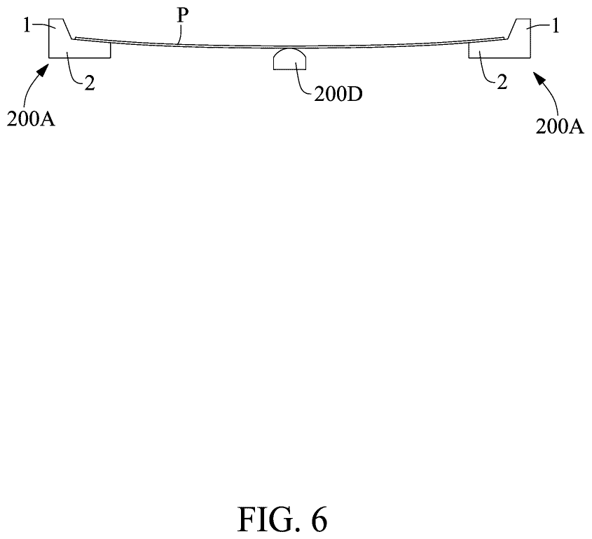

Referring to FIG. 6, using a substrate with a length being 60 cm, a width being 60 cm, a thickness being 1 mm, and a density being 2.38 g/cm³ as an example, a weight of the substrate is approximately 856.8 g. After the substrate is mounted into a semiconductor container including support apparatuses 200A on two sides and a support apparatus 200D, a warping dimension of the substrate on two sides is only approximately 0.01 mm. For a substrate whose thickness is reduced to 0.5 mm but other conditions are the same, a warping dimension of the substrate on two sides is only approximately 0.03 mm. In comparison with the foregoing known structure, the warping dimension of the substrate on the two sides is significantly reduced, and a contact area between the substrate and the support apparatus 200A is significantly increased. The foregoing data of the substrate is only an exemplary embodiment, instead of data limited by the present disclosure.

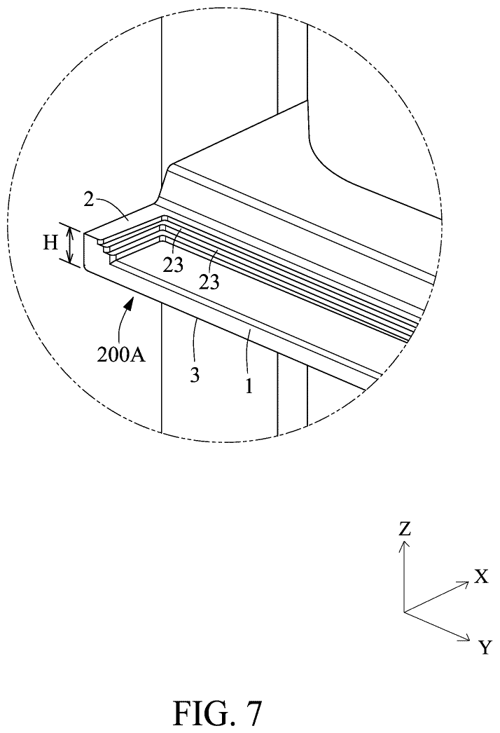

Referring to FIG. 2 and FIG. 7, in an embodiment of the present disclosure, at least one fault portion 23 is disposed on the bearing surface 2 of the support apparatus 200A. For example, in an embodiment in which the semiconductor container 100 is in a front opening form, a plurality of support apparatuses 200A of this embodiment may be bound to each of left and right sides that are opposite in the direction X inside the semiconductor container 100. At least one fault portion 23 may be disposed on each of the support apparatuses 200A. A quantity of fault portions 23 may be at least one. When there are a plurality of fault portions 23, the bearing surface 2 is presented as step-shaped fault portions with different heights and different areas. The step-shaped fault portions may all be configured to bear the contact surface of the semiconductor substrate.

More specifically, the body 1 includes a lower surface 3 opposite to the bearing surface 2. The lower surface 3 and the bearing surface 2 have a thickness H. The plurality of fault portions 23 are based on the lower surface 3. A thickness between the plurality of fault portions 23 and the lower surface 3 is gradually reduced, to present the step-shaped fault portions with the different heights and the different areas. A height between adjacent fault portions 23 in the direction Z is approximately less than 1 mm, for example, ranges from 0.5 mm to 0.8 mm, and a width in the direction X is approximately less than 2 mm, for example, ranges from 1 mm to 1.5 mm. In addition, the adjacent fault portions 23 form the bearing surface 2 of the support apparatus 200A.

Based on this, each semiconductor substrate placed in the semiconductor container 100 may be borne by a fault portion 23 best matching a size of the semiconductor substrate on the support apparatus 200A, to resolve a problem that the semiconductor substrate slides on the support apparatus 200A due to a size error.

In addition, each fault portion 23 is preferably formed in an L-shape or a U-shape whose opening faces an internal center of the semiconductor container 100, so that a side wall of each fault portion 23 can help limit a position of the semiconductor substrate, and reduce sliding of the semiconductor substrate on the support apparatus 200A, in particular, sliding in the direction X and the direction Y. Therefore, a better fixing effect can be achieved.

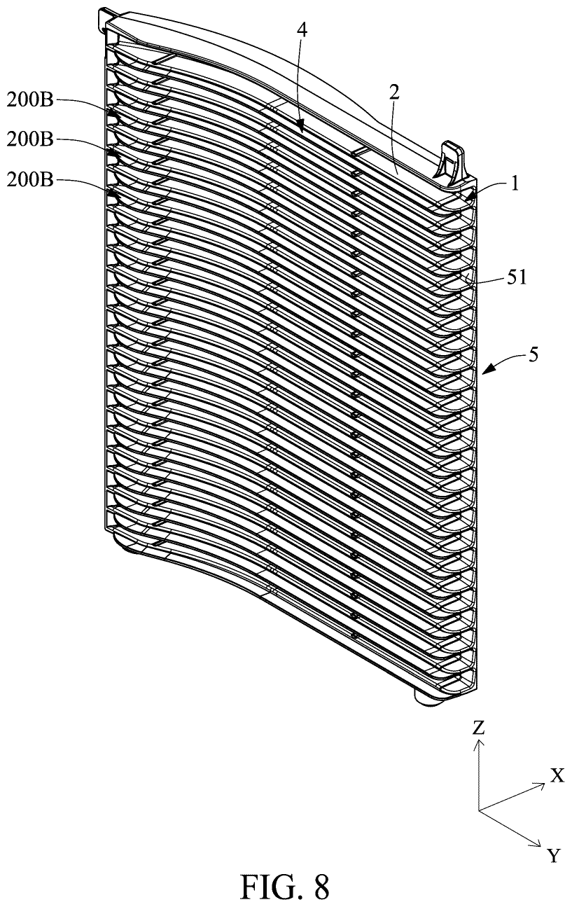

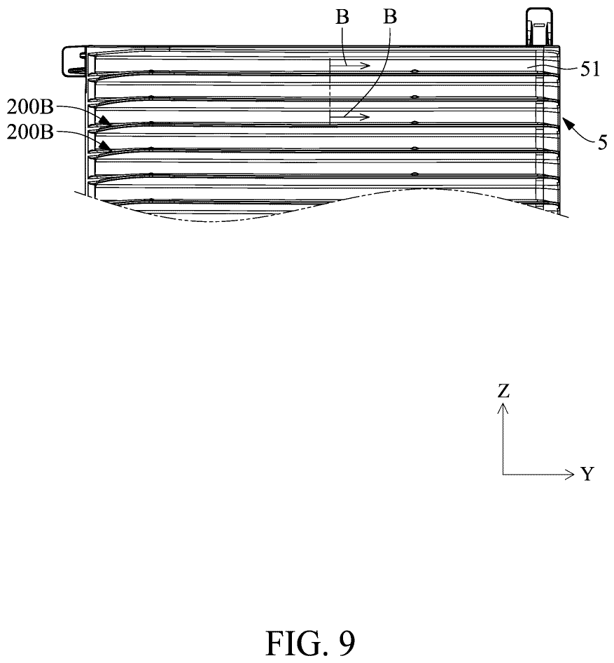

FIG. 8 to FIG. 10 show Embodiment 2 of a support apparatus 200B of the present disclosure. At least one particle collection slot 4 may be disposed on the support apparatus 200B of this embodiment, and is configured to collect particles T generated during sliding of a semiconductor substrate P, to prevent the particles T from falling onto the support apparatus 200B below.

For example, referring to FIG. 2, in an embodiment in which the semiconductor container 100 is a front opening unified pod, a plurality of support apparatuses 200B of this embodiment may be bound to each of left and right sides that are opposite in the direction X inside the semiconductor container 100. In the embodiments shown in FIG. 8 to FIG. 10, the plurality of support apparatuses 200B may be integrally connected to a connection plate 5, and protrude from an inner side surface 51 of the connection plate 5. In addition, the plurality of support apparatuses 200B are spaced apart in the longitudinal direction. The connection plate 5 is detachably bound to a left side or a right side inside the semiconductor container 100.

At least one particle collection slot 4 is disposed on an inner side and/or outer side of a bearing surface 2 of the support apparatus 200B. The inner side of the bearing surface 2 herein is a side of the bearing surface 2 facing the connection plate 5, and the other side of the bearing surface 2 is the outer side. In other words, the outer side of the bearing surface 2 faces an internal center of the semiconductor container 100.

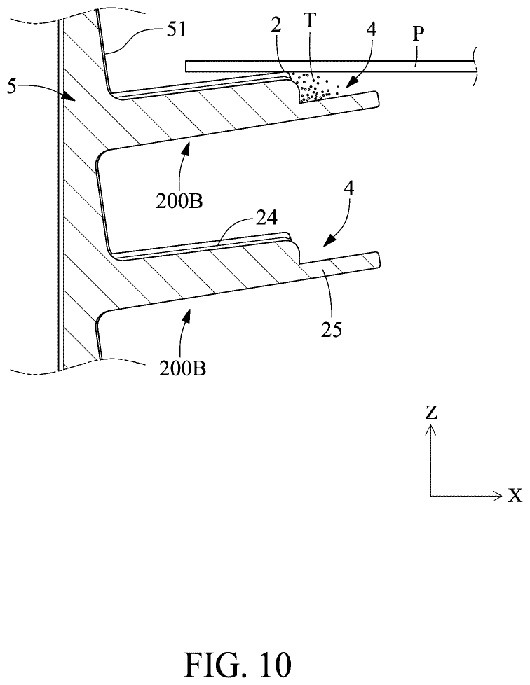

As shown in FIG. 10, an example in which the particle collection slot 4 is located on the outer side of the bearing surface 2 is used. The bearing surface 2 is located on an upper surface of a body 1. The bearing surface 2 includes a plane 24 and at least one extension portion 25 extending upward from the plane 24. At least one particle collection slot 4 is defined between the plane 24 and the extension portion 25. For example, near a free end of the extension portion 25, the plane 24 and the extension portion 25 are different regions. When the extension portion 25 is slightly lower than the plane 24, a step is formed, and the extension portion 25 slightly extends upward toward a direction of the internal center of the semiconductor container 100, so that the plane 24 serves as a bearing position of the semiconductor substrate P, and the extension portion 25 serves as a particle collection position. The step between the plane 24 and the extension portion 25 serves as the particle collection slot 4. In this way, when the semiconductor substrate P is in contact with the bearing surface 2 of the support apparatus 200B, or the particles T are generated due to sliding of the semiconductor substrate P during transportation, the particles T may fall downward into the particle collection slot 4, instead of directly falling onto the semiconductor substrate P below. Therefore, cross contamination between layers of semiconductor substrates P can be effectively avoided, thereby improving a production yield rate.

The plane 24 and the extension portion 25 may be connected in an integrally formed manner, or may be two combinable elements.

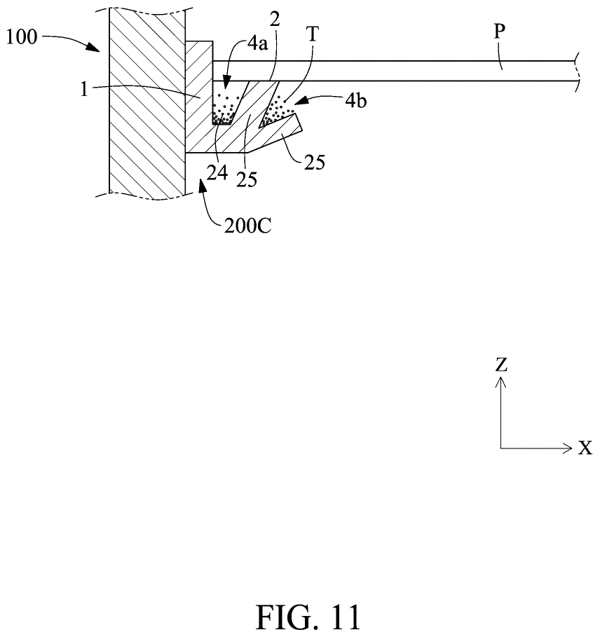

In one embodiment, using an example in which the particle collection slot 4 is located on the inner side of the bearing surface 2, the particle collection slot 4 may be formed between the bearing surface 2 and the inner side surface 51 of the connection plate 5. Alternatively, as shown in FIG. 11, the particle collection slot 4 is formed between the bearing surface 2 and a side wall inside the semiconductor container 100. At least a portion of the semiconductor substrate P near its edge located on an inner side of the bearing surface 2 and is positioned above the particle collection slot 4.

FIG. 11 shows a support apparatus 200C of Embodiment 3 of the present disclosure. The support apparatus 200C may form a particle collection slot 4 on each of an inner side and an outer side of a bearing surface 2, but a form and a quantity of the particle collection slots 4 do not limit the present disclosure.

The bearing surface 2 may include a plane 24 and two extension portions 25 extending upward from the plane 24. The extension portions 25 may extend upward from the middle and an outer side of the plane 24, to define a particle collection slot 4a and a particle collection slot 4b. A projection that is of a free end of the extension portion 25 extending upward from the middle of the plane 24 and that is in the direction Z may be located in the particle collection slot 4b on an outer side, to improve a particle collection effect. The particle collection slot 4b assists in particle collection, to better prevent the particles T from falling downward onto the support apparatus 200C below.

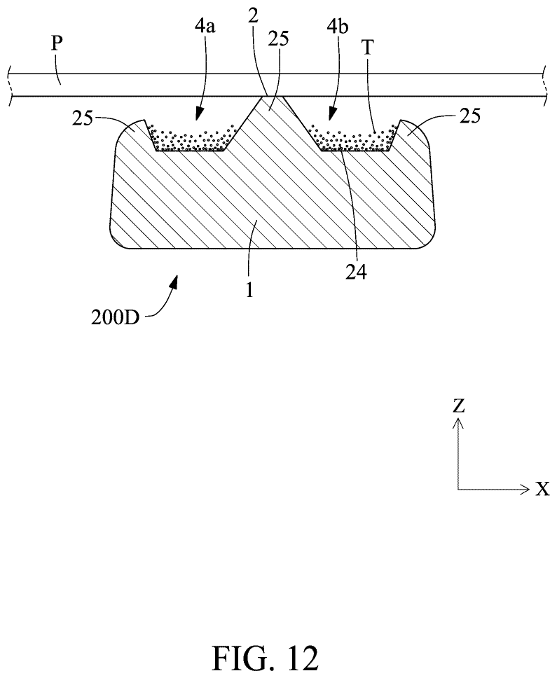

Similarly, referring to FIG. 2 and FIG. 12, a support apparatus 200D in Embodiment 4 may be configured at a middle position inside the semiconductor container 100, that is, the support apparatus 200D may be the foregoing intermediate lifting member. The support apparatus 200D may be processed into a structure of a slot shape, a groove shape, a mountain shape, or the like, to form at least one particle collection slot at an upper half of the support apparatus 200d.

For example, an extension portion 25 of the support apparatus 200D may extend upward from the middle and two outer sides of the plane 24, to define at least two particle collection regions, a particle collection slot 4a, and a particle collection slot 4b. The extension portion 25 serves as a lower surface in contact with the semiconductor substrate P, and a step between the plane 24 and the extension portion 25 serves as the particle collection region. The particle collection slot 4a and the particle collection slot 4b both perform particle collection, to better prevent the particles T from falling downward onto the support apparatus 200D below. Based on this, regardless of whether the semiconductor substrate P slides to the left or the right, almost all the particles T generated due to friction of the semiconductor substrate P can fall into the two particle collection slots 4a and 4b, so that an overall particle collection effect can be further improved.

It should be noted that the extension portion 25 may be a slightly inclined surface, so that the particles T can be better collected in the particle collection slots 4a and 4b along the inclined surface. In addition to the foregoing semiconductor container of the front opening unified pod, the support apparatus is also applicable to a semiconductor container of a top opening carrier. In addition, when there is no contradiction, the support apparatus of the embodiments of the present disclosure can simultaneously include a plurality of structural features described above, so that the present disclosure is not limited by types disclosed in the figures of the embodiments.

The present disclosure is disclosed above by using preferred embodiments. However, a person skilled in the art should understand that the embodiments are only used to describe the present disclosure, and should not be understood as a limitation to the scope of the present disclosure. It should be noted that any equivalent modification or replacement of the embodiments should be included in a range of the present disclosure. Therefore, the protection scope of the present disclosure should be defined by the scope of the appended claims, and the scope of the appended claims should be given the broadest reasonable interpretation, to include all modifications, similar arrangement, and procedures therein.

What is claimed is:

1. A support apparatus, configured in a semiconductor container, wherein the support
apparatus comprises:
a body; and
a bearing surface, located on an upper surface of the body, wherein the bearing surface comprises:
a first inclined surface, gradually protruding obliquely from the bearing surface toward an opening of the semiconductor container; and
a second inclined surface, wherein the second inclined surface gradually protrudes obliquely toward an inner rear wall of the semiconductor container, wherein
the bearing surface is configured to bear a contact surface of a semiconductor substrate, and the contact surface makes surface contact along the first inclined surface and along the second inclined surface that are different inclined surfaces.

2. The support apparatus according to claim 1, wherein the first inclined surface and the second inclined surface each form an included angle less than 7 degrees with a horizontal surface.

3. A support apparatus, configured in a semiconductor container, wherein the support
apparatus comprises:
a body; and
a bearing surface, comprising at least one fault portion, and located on an upper surface of the body, wherein the bearing surface comprises:
a first inclined surface, gradually protruding obliquely from the bearing surface toward an opening of the semiconductor container; and
a second inclined surface, wherein the second inclined surface gradually protrudes obliquely toward an inner rear wall of the semiconductor container, wherein
the bearing surface is configured to bear a contact surface of a semiconductor substrate, and the contact surface makes surface contact along the first inclined surface and along the second inclined surface that are different inclined surfaces.

4. The support apparatus according to claim 3, wherein when there are a plurality of fault portions, the bearing surface is presented as step-shaped fault portions with different heights and different areas, wherein the step-shaped fault portions are configured to bear the contact surface of the semiconductor substrate.

5. The support apparatus according to claim 4, wherein the body comprises a lower surface opposite to the bearing surface, the lower surface and the bearing surface have a thickness, the plurality of fault portions are based on the lower surface, and the plurality of fault portions and the lower surface are gradually thinned, to present the step-shaped fault portions with the different heights and the different areas.

6. The support apparatus according to claim 4, wherein a height between adjacent fault portions is less than 1 mm, and a width therebetween is less than 2 mm.

7. The support apparatus according to claim 3, wherein the first inclined surface and the second inclined surface each form an included angle less than 7 degrees with a horizontal surface.

8. A support apparatus, configured in a semiconductor container, wherein the support
apparatus comprises:
a body; and
a bearing surface, comprising a plane and at least one extension portion extending upward from the plane, wherein at least one particle collection slot is defined between the plane and the extension portion, the bearing surface is located on an upper surface of the body, and the bearing surface comprises:
a first inclined surface, gradually protruding obliquely from the bearing surface toward an opening of the semiconductor container; and
a second inclined surface, wherein the second inclined surface gradually protrudes obliquely toward an inner rear wall of the semiconductor container, wherein
the bearing surface is configured to bear a contact surface of a semiconductor substrate, and the contact surface makes surface contact along the first inclined surface and along the second inclined surface that are different inclined surfaces.

9. The support apparatus according to claim 8, wherein when the support apparatus is configured on a side wall inside the semiconductor container, the extension portion extends upward from a middle and an outer side of the plane, to define at least two particle collection slots.

10. The support apparatus according to claim 8, wherein when the support apparatus is configured at a middle position inside the semiconductor container, the extension portion extends upward from a middle and two outer sides of the plane, to define at least two particle collection slots.
